(19) United States
(12) Patent Application Publication
(10) Pub. No.: US 2017/0133353 A1
(43) Pub. Date: May 11, 2017

(54) SEMICONDUCTOR ASSEMBLY WITH THREE DIMENSIONAL INTEGRATION AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW); Wei-Kuang Pan, Taipei (TW)

(21) Appl. No.: 15/415,846

(22) Filed: Jan. 25, 2017

Related U.S. Application Data
(63) Continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/289,126 is a continuation-in-part of application No. 15/166,185, filed on May 26, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
(60) Provisional application No. 62/166,771, filed on May 27, 2015.

(51) Int. Cl. H01L 25/065; H01L 23/00; H01L 23/367; H01L 21/683; H01L 25/00; H01L 21/56; H01L 21/48; H01L 23/538; H01L 23/31

(52) U.S. Cl. CPC H01L 25/0657; H01L 23/5386; H01L 23/5389; H01L 24/49; H01L 23/3675; H01L 23/3128; H01L 24/17; H01L 25/50; H01L 24/85; H01L 21/56; H01L 23/5383; H01L 23/5384; H01L 21/4857; H01L 21/6835; H01L 2225/0651; H01L 2225/06517; H01L 2225/06589; H01L 2225/06572; H01L 2225/06548; H01L 2224/48091; H01L 2224/48106; H01L 2224/48227; H01L 2224/16055; H01L 2224/16057; H01L 2224/16113; H01L 2224/16227; H01L 2924/15153; H01L 2924/19105; H01L 2924/19107; H01L 2221/68345; H01L 2924/15747; H01L 2924/15763; H01L 2924/01022; H01L 2224/81191; H01L 2224/81203; H01L 2224/81207; H01L 2224/81815; H01L 2221/68381; H01L 2224/81005; H01L 2224/45144; H01L 2224/45147; H01L 2224/45124; H01L 2224/4845; H01L 2224/48455; H01L 2225/06586; H01L 2924/15311

(57) ABSTRACT

A semiconductor assembly includes a face-to-face semiconductor sub-assembly electrically coupled to a circuit board by bonding wires. The face-to-face semiconductor sub-assembly includes top and bottom devices assembled on opposite sides of a routing circuitry, and is disposed in a through opening of the circuit board. The bonding wires provide electrical connections between the routing circuitry and the circuit board to interconnect the devices face-to-face assembled in the sub-assembly with the circuit board for next-level connection from two opposite sides of the circuit board.

### CROSS REFERENCE TO RELATED APPLICATIONS

This application is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The entirety of each of said Applications is incorporated herein by reference.

### FIELD OF THE INVENTION

The present invention relates to a semiconductor assembly and, more particularly, to a semiconductor assembly having a face-to-face semiconductor sub-assembly electrically connected to a circuit board through bonding wires, and a method of making the same.

### DESCRIPTION OF RELATED ART

Market trends of multimedia devices demand for faster and slimmer designs. One of assembly approaches is to interconnect two devices with “face-to-face” configuration so that the routing distance between the two devices can be the shortest possible. As the stacked devices can talk directly to each other with reduced latency, the assembly's signal integrity and additional power saving capability are greatly improved. As a result, the face-to-face semiconductor assembly offers almost all of the true 3D IC stacking advantages without the need of expensive through-silicon-via (TSV) in the stacked chips.

U.S. Pat. Nos. 8,008,121, 8,519,537 and 8,558,395 disclose various assembly structures having an interposer disposed in between the face-to-face chips. Although there is no TSV in the stacked chips, the TSV in the interposer that serves for circuitry routing between chips induces complicated manufacturing processes, high yield loss and excessive cost.

For the reasons stated above, and for other reasons stated below, an urgent need exists to provide a three dimensional semiconductor assembly that can address high packaging density and better signal integrity requirements.

### SUMMARY OF THE INVENTION

The objective of the present invention is to provide a semiconductor assembly in which a face-to-face semiconductor sub-assembly is disposed in a through opening of a circuit board and electrically connected to the circuit board. The circuit board not only provides mechanical housing for the face-to-face stacked sub-assembly, it also offers electrical fan-out routing for the sub-assembly in conjunction with a plurality of bonding wires, thereby effectively improving electrical performances of the assembly.

In accordance with the foregoing and other objectives, the present invention provides a semiconductor assembly having a face-to-face semiconductor sub-assembly electrically connected to a circuit board through bonding wires. The face-to-face semiconductor sub-assembly includes a first device, a second device and a routing circuitry. In a preferred embodiment, the first device is spaced from and face-to-face electrically connected to the second device through the routing circuitry; the routing circuitry provides primary fan-out routing and the shortest interconnection distance between the first device and the second device; the circuit board laterally surrounds the sub-assembly and provides further fan-out routing; and the bonding wires are attached to the routing circuitry and the circuit board to provide electrical connections therebetween.

Accordingly, the present invention provides a semiconductor assembly, comprising: a face-to-face semiconductor sub-assembly that includes a first device, a second device and a routing circuitry, wherein the first device is electrically coupled to a first surface of the routing circuitry and the second device is electrically coupled to a second surface of the routing circuitry opposite to the first surface; a circuit board having a through opening, wherein the face-to-face semiconductor sub-assembly is disposed in the through opening of the circuit board; and a plurality of bonding wires that electrically couple the routing circuitry to the circuit board.

Additionally, the present invention provides a method of making a semiconductor assembly, comprising: providing a face-to-face semiconductor sub-assembly that includes a first device and a second device face-to-face electrically connected to each other; providing a circuit board that has a through opening; disposing the face-to-face semiconductor sub-assembly in the through opening of the circuit board; electrically coupling the face-to-face semiconductor sub-assembly to the circuit board through a plurality of bonding wires; and electrically coupling a third device to the circuit board.

Unless specifically indicated or using the term “then” between steps, or steps necessarily occurring in a certain order, the sequence of the above-mentioned steps is not limited to that set forth above and may be changed or reordered according to desired design.

The semiconductor assembly and the method of making the same according to the present invention have numerous advantages. For instance, face-to-face electrically coupling the first and second devices to both opposite sides of the routing circuitry can offer the shortest interconnect distance between the first and second devices. Attaching the bonding wires to the sub-assembly and the circuit board can offer a reliable connecting channel to interconnect the devices assembled in the sub-assembly with the circuit board for next-level connection from two opposite sides of the circuit board.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of the structure with routing traces formed on a sacrificial carrier in accordance with the first embodiment of the present invention;

FIG. 2 is a cross-sectional view of the structure of FIG. 1 further provided with a dielectric layer and via openings in accordance with the first embodiment of the present invention;

FIG. 3 is a cross-sectional view of the structure of FIG. 2 further provided with conductive traces in accordance with the first embodiment of the present invention;

FIG. 4 is a cross-sectional view of the structure of FIG. 3 further provided with first device in accordance with the first embodiment of the present invention;

FIG. 5 is a cross-sectional view of the structure of FIG. 4 further provided with a molding compound material in accordance with the first embodiment of the present invention;

FIG. 6 is a cross-sectional view of the structure of FIG. 5 after removal of the sacrificial carrier in accordance with the first embodiment of the present invention;

FIG. 7 is a cross-sectional view of the structure of FIG. 6 further provided with second device to finish the fabrication of a face-to-face semiconductor sub-assembly in accordance with the first embodiment of the present invention;

FIG. 8 is a cross-sectional view of a circuit board in accordance with the first embodiment of the present invention;

FIG. 9 is a cross-sectional view of the structure of FIG. 8 further provided with the face-to-face semiconductor sub-assembly of FIG. 7 in accordance with the first embodiment of the present invention;

FIG. 10 is a cross-sectional view of the structure of FIG. 9 further provided with bonding wires to finish the fabrication of a semiconductor assembly in accordance with the first embodiment of the present invention;

FIG. 11 is a cross-sectional view of the structure of FIG. 10 further provided with an encapsulant in accordance with the first embodiment of the present invention;

FIG. 12 is a cross-sectional view of the structure of FIG. 11 further provided with solder balls and a third device in accordance with the first embodiment of the present invention;

FIG. 13 is a cross-sectional view of another aspect of the semiconductor assembly in accordance with the first embodiment of the present invention;

FIG. 14 is a cross-sectional view of the structure of FIG. 13 further provided with an encapsulant, solder balls and a third device in accordance with the first embodiment of the present invention;

FIG. 15 is a cross-sectional view of the structure of FIG. 13 further provided with a third device and passive components in accordance with the first embodiment of the present invention;

FIG. 16 is a cross-sectional view of the structure of FIG. 15 further provided with encapsulants and solder balls in accordance with the first embodiment of the present invention;

FIG. 17 is a cross-sectional view of yet another aspect of the semiconductor assembly in accordance with the first embodiment of the present invention;

FIG. 18 is a cross-sectional view of the structure of FIG. 17 further provided with an encapsulant in accordance with the first embodiment of the present invention;

FIG. 19 is a cross-sectional view of yet another aspect of the semiconductor assembly in accordance with the first embodiment of the present invention;

FIG. 20 is a cross-sectional view of the structure of FIG. 19 further provided with encapsulants in accordance with the first embodiment of the present invention;

FIG. 21 is a cross-sectional view of the structure of FIG. 20 further provided with solder balls and a third device in accordance with the first embodiment of the present invention;

FIG. 22 is a cross-sectional view of the structure of FIG. 19 further provided with a third device and passive components in accordance with the first embodiment of the present invention;

FIG. 23 is a cross-sectional view of the structure of FIG. 22 further provided with encapsulants and solder balls in accordance with the first embodiment of the present invention;

FIG. 24 is a cross-sectional view of the structure with a face-to-face semiconductor sub-assembly accommodated in a through opening of a circuit board in accordance with the second embodiment of the present invention;

FIG. 25 is a cross-sectional view of the structure of FIG. 24 further provided with bonding wires in accordance with the second embodiment of the present invention;

FIG. 26 is a cross-sectional view of the structure of FIG. 25 further provided with an encapsulant and a heat spreader to finish the fabrication of a semiconductor assembly in accordance with the second embodiment of the present invention;

FIG. 27 is a cross-sectional view of the structure of FIG. 26 further provided with solder balls and a third device in accordance with the second embodiment of the present invention;

FIG. 28 is a cross-sectional view of the structure of FIG. 11 further provided with a third device and metal posts in accordance with the third embodiment of the present invention;

FIG. 29 is a cross-sectional view of the structure of FIG. 28 further provided with an encapsulant to finish the fabrication of a semiconductor assembly in accordance with the third embodiment of the present invention;

FIG. 30 is a cross-sectional view of the structure of FIG. 29 further provided with solder balls and a fourth device in accordance with the third embodiment of the present invention;

FIG. 31 is a cross-sectional view of another aspect of the semiconductor assembly in accordance with the third embodiment of the present invention;

FIG. 32 is a cross-sectional view of yet another aspect of the semiconductor assembly in accordance with the third embodiment of the present invention;

FIG. 33 is a cross-sectional view of yet another aspect of the semiconductor assembly in accordance with the third embodiment of the present invention;

FIG. 34 is a cross-sectional view of the structure of FIG. 13 further provided with a third device and metal posts in accordance with the fourth embodiment of the present invention;

FIG. 35 is a cross-sectional view of the structure of FIG. 34 further provided with encapsulants to finish the fabrication of a semiconductor assembly in accordance with the fourth embodiment of the present invention; and

FIG. 36 is a cross-sectional view of the structure of FIG. 35 further provided with solder balls and a fourth device in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

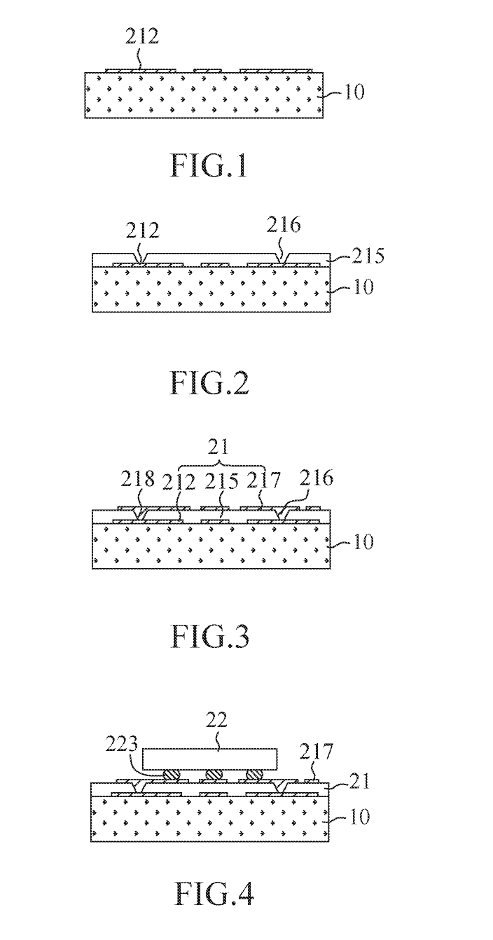

FIGS. 1-10 are schematic views showing a method of making a semiconductor assembly that includes a routing circuitry 21, a first device 22, a molding compound material 25, a second device 27, a circuit board 30 and bonding wires 41 in accordance with the first embodiment of the present invention.

FIG. 1 is a cross-sectional view of the structure with routing traces 212 formed on a sacrificial carrier 10. The sacrificial carrier 10 typically is made of copper, aluminum, iron, nickel, tin, stainless steel, silicon, or other metals or alloys, but any other conductive or non-conductive material also may be used. In this embodiment, the sacrificial carrier 10 is made of an iron-based material. The routing traces 212 typically are made of copper and can be pattern deposited by numerous techniques, such as electroplating, electroless plating, evaporating, sputtering or their combinations, or be thin-film deposited followed by a metal patterning process. For a conductive sacrificial carrier 10, the routing traces 212 are deposited typically by plating of metal. The metal patterning techniques include wet etching, electro-chemical etching, laser-assist etching, and their combinations with an etch mask (not shown) thereon that defines the routing traces 212.

FIG. 2 is a cross-sectional view of the structure with a dielectric layer 215 on the sacrificial carrier 10 as well as the routing traces 212 and via openings 216 in the dielectric layer 215. The dielectric layer 215 is deposited typically by lamination or coating, and contacts and covers and extends laterally on the sacrificial carrier 10 and the routing traces 212 from above. The dielectric layer 215 typically has a thickness of 50 microns, and can be made of epoxy resin, glass-epoxy, polyimide, or the like. After the deposition of the dielectric layer 215, the via openings 216 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The via openings 216 extend through the dielectric layer 215 and are aligned with selected portions of the routing traces 212.

Referring now to FIG. 3, conductive traces 217 are formed on the dielectric layer 215 by metal deposition and metal patterning process. The conductive traces 217 extend from the routing traces 212 in the upward direction, fill up the via openings 216 to form metallized vias 218 in direct contact with the routing traces 212, and extend laterally on the dielectric layer 215. As a result, the conductive traces 217 can provide horizontal signal routing in both the X and Y directions and vertical routing through the via openings 216 and serve as electrical connections for the routing traces 212.

The conductive traces 217 can be deposited as a single layer or multiple layers by any of numerous techniques, such as electroplating, electroless plating, evaporating, sputtering, or their combinations. For instance, they can be deposited by first dipping the structure in an activator solution to render the dielectric layer 215 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the conductive traces 217 by any of numerous techniques such as wet etching, electro-chemical etching, laser-assist etching, or their combinations, with an etch mask (not shown) thereon that defines the conductive traces 217.

At this stage, the formation of a routing circuitry 21 on the sacrificial carrier 10 is accomplished. In this illustration, the routing circuitry 21 is a multi-layered buildup circuitry and includes routing traces 212, a dielectric layer 215 and conductive traces 217.

FIG. 4 is a cross-sectional view of the structure with a first device 22 electrically coupled to the routing circuitry 21. The first device 22, illustrated as a bare chip, can be electrically coupled to the conductive traces 217 of the routing circuitry 21 using first bumps 223 in contact with the first device 22 and the routing circuitry 21 by thermal compression, solder reflow or thermosonic bonding.

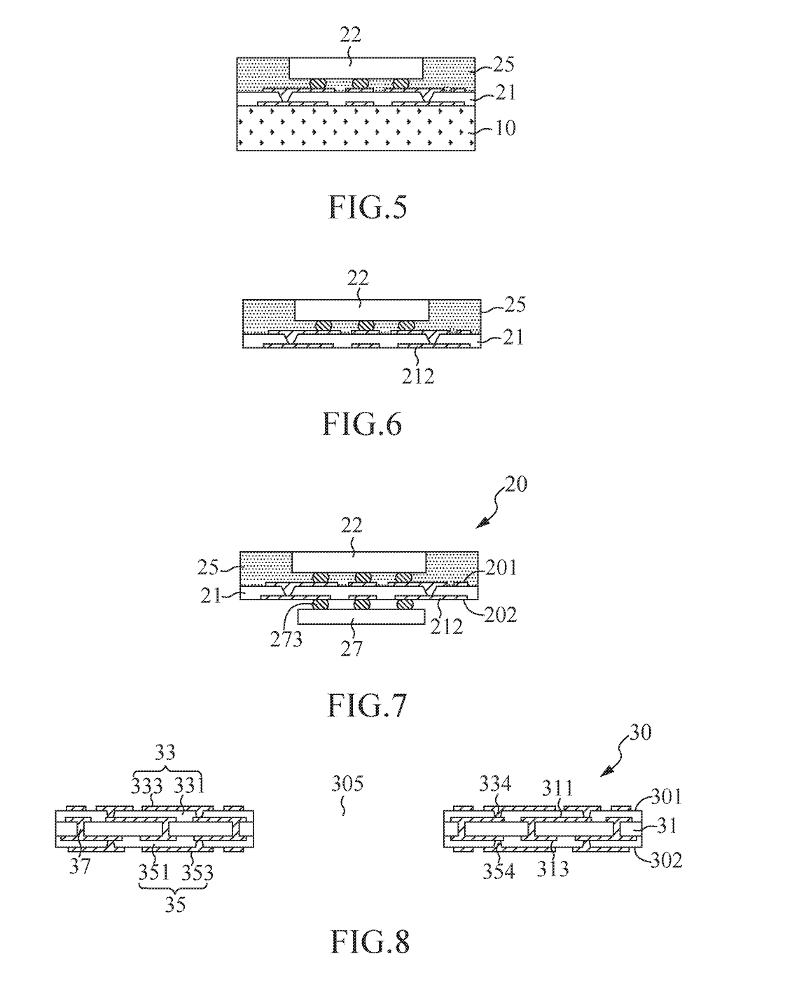

FIG. 5 is a cross-sectional view of the structure with a molding compound material 25 on the routing circuitry 21 and around the first device 22 by, for example, resin-glass lamination, resin-glass coating or molding. The molding compound material 25 covers the routing circuitry 21 from above and surrounds and conformally coats and covers sidewalls of the first device 22. As an alternative, the step of providing the molding compound material 25 may be omitted.

FIG. 6 is a cross-sectional view of the structure after removal of the sacrificial carrier 10. The sacrificial carrier 10 can be removed to expose the routing circuitry 21 from below by numerous techniques, such as wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 10 made of an iron-based material is removed by a chemical etching solution that is selective between copper and iron so as to prevent the copper routing traces 212 from being etched during removal of the sacrificial carrier 10.

FIG. 7 is a cross-sectional view of the structure with a second device 27 electrically coupled to the routing circuitry 21. The second device 27, illustrated as a bare chip, can be electrically coupled to the routing traces 212 of the routing circuitry 21 using second bumps 273 in contact with the second device 27 and the routing circuitry 21 by thermal compression, solder reflow or thermosonic bonding.

At this stage, a face-to-face semiconductor sub-assembly 20 is accomplished and includes a routing circuitry 21, a first device 22, a molding compound material 25, and a second device 27. The first device 22 and the second device 27 are electrically coupled to first and second surfaces 201, 202 of the routing circuitry 21, respectively, and the molding compound material 25 is disposed over the first surface 201 and around the first device 22.

FIG. 8 is a cross-sectional view of a circuit board 30 having a through opening 305. The circuit board 30 includes a core layer 31, a first buildup circuitry 33, a second buildup circuitry 35 and metallized through vias 37. The first buildup circuitry 33 and the second buildup circuitry 35 are respectively disposed on both sides of the core layer 31, and each of them includes an insulating layer 331, 351 and conductive traces 333, 353. The insulating layers 331, 351 respectively cover both sides of the core layer 31 from above and below, and the conductive traces 333, 353 respectively extend laterally on the insulating layers 331, 351 and include conductive vias 334, 354 in the insulating layers 331, 351. The conductive vias 334, 354 contact first and second patterned wiring layers 311, 313 of the core layer 31, and extend through the insulating layers 331, 351. The metallized through vias 37 extend through the core layer 31 to provide electrical connections between the first buildup circuitry 33 and the second buildup circuitry 35. The through opening 305 extends through the circuit board 30 between first and second sides 301, 302 thereof, and has a dimension that is almost the same or a little larger than the face-to-face semiconductor sub-assembly 20.

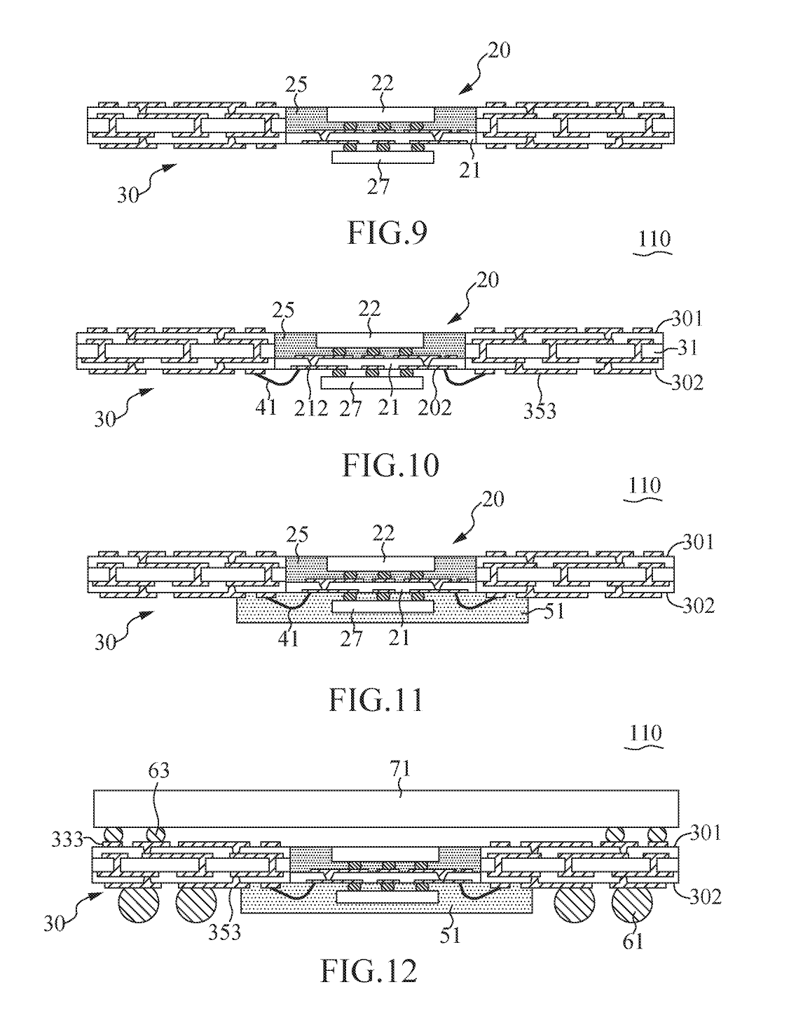

FIG. 9 is a cross-sectional view of the structure with the face-to-face semiconductor sub-assembly 20 of FIG. 7 accommodated in the through opening 305 of the circuit board 30. The face-to-face semiconductor sub-assembly 20 is aligned with and inserted into the through opening 305 of the circuit board 30. In this illustration, the routing circuitry 21, the first device 22 and the molding compound material 25 are located within the through opening 305 of the circuit board 30, whereas the second device 27 is located beyond the second side 302 of the circuit board 30. The peripheral edges of the face-to-face semiconductor sub-assembly 20 can be bonded to the sidewalls of the through opening 305 through an adhesive (not shown in figures) dispensed therebetween.

FIG. 10 is a cross-sectional view of the structure with bonding wires 41 attached to the face-to-face semiconductor sub-assembly 20 and the circuit board 30 typically by gold or copper ball bonding, or gold or aluminum wedge bonding. The bonding wires 41 contact and are electrically coupled to the routing traces 212 at the second surface 202 of the routing circuitry 21 and the conductive traces 353 at the second side 302 of the circuit board 30. As a result, the first device 22 and the second device 27 are electrically connected to the circuit board 30 through the routing circuitry 21 and the bonding wires 41.

Accordingly, as shown in FIG. 10, a semiconductor assembly 110 is accomplished and includes a face-to-face semiconductor sub-assembly 20 electrically connected to a circuit board 30 by bonding wires 41. In this illustration, the face-to-face semiconductor sub-assembly 20 includes a routing circuitry 21, a first device 22, a molding compound material 25 and a second device 27.

The first device 22 is flip-chip electrically coupled to the routing circuitry 21 from one side of the routing circuitry 21 and sealed in the molding compound material 25. The second device 27 is flip-chip electrically coupled to the routing circuitry 21 from the other side of the routing circuitry 21 and face-to-face connected to the first device 22 through the routing circuitry 21. As such, the routing circuitry 21 offers primary fan-out routing and the shortest interconnection distance between the first device 22 and the second device 27. The circuit board 30 surrounds the peripheral edges of the routing circuitry 21 and the molding compound material 25, and is electrically coupled to the routing circuitry 21 by the bonding wires 41.

FIG. 11 is a cross-sectional view of the semiconductor assembly 110 of FIG. 10 further provided with an encapsulant 51. The encapsulant 51 covers the bonding wires 41 and the face-to-face semiconductor sub-assembly 20 as well as selected portions of the circuit board 30 from below, and surrounds and conformally coats and covers sidewalls of the second device 27 in the lateral directions. Additionally, when no adhesive is dispensed between the peripheral edges of the face-to-face semiconductor sub-assembly 20 and the interior sidewalls of the circuit board 30 in the previous process, the encapsulant 51 may further fill up gaps (not shown in the figures) between the peripheral edges of the face-to-face semiconductor sub-assembly 20 and the interior sidewalls of the circuit board 30. As a result, the encapsulant 51 can provide secure robust mechanical bonds to attach the face-to-face semiconductor sub-assembly 20 to the circuit board 30.

FIG. 12 is a cross-sectional view of the semiconductor assembly 110 of FIG. 11 further provided with solder balls 61 and a third device 71 mounted on the opposite sides of the circuit board 30, respectively. The solder balls 61 are mounted on conductive traces 353 at the second side 302 of the circuit board 30, and extend beyond the outer surface of the encapsulant 51 in the downward direction to ensure successful next-level connection. The third device 71 can be a ball grid array package or a bumped chip, and is electrically coupled to the circuit board 30 through a plurality of solder balls 63 in contact with the third device 71 and the conductive traces 333 at the first side 301 of the circuit board 30.

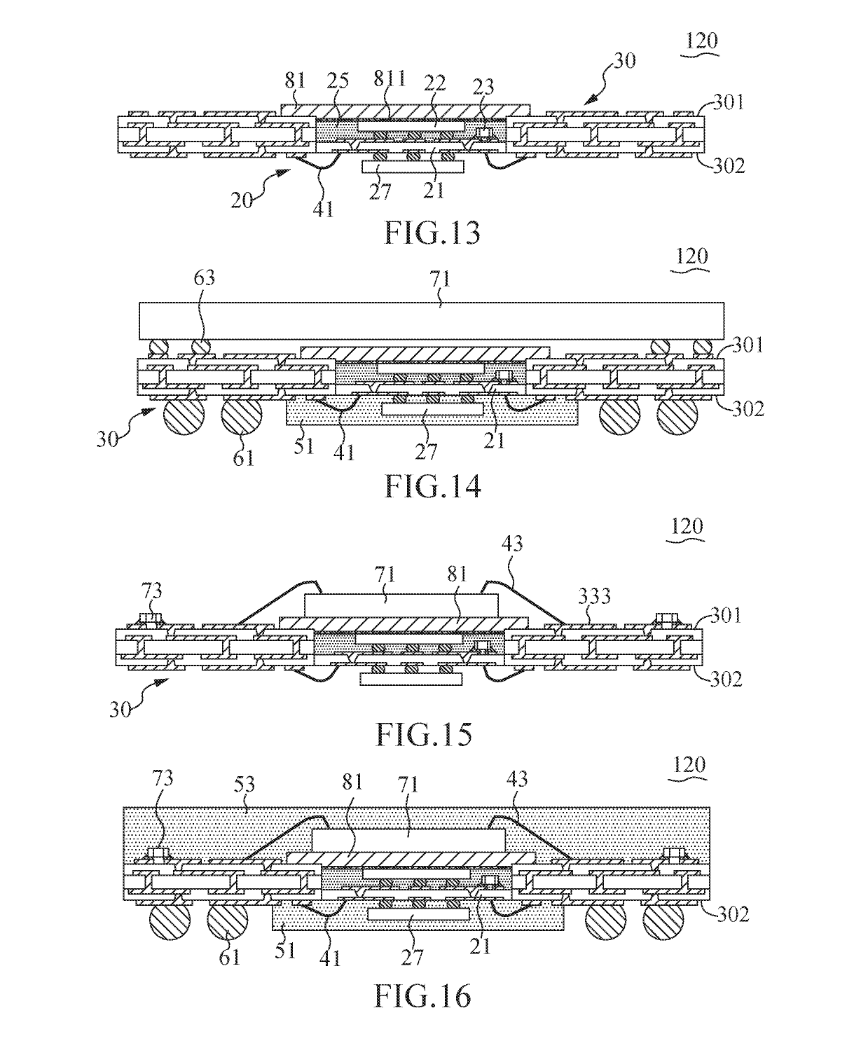

FIG. 13 is a cross-sectional view of another aspect of the semiconductor assembly according to the first embodiment of the present invention. The semiconductor assembly 120 is similar to that illustrated in FIG. 10, except that it further includes a heat spreader 81 attached to the first device 22 using a thermally conductive adhesive 811, and the face-to-face semiconductor sub-assembly 20 further includes a passive component 23 electrically coupled to the routing circuitry 21 and sealed in the molding compound material 25. The heat spreader 81 typically is made of a thermally conductive material, such as metal, alloy, silicon, ceramic or graphite. In this illustration, the heat spreader 81 is disposed over the first side 301 of the circuit board 30, and has a selected portion further extending into the through opening 305 of the circuit board 30 to be thermally conductible to the first device 22.

FIG. 14 is a cross-sectional view of the semiconductor assembly 120 of FIG. 13 further provided with an encapsulant 51, solder balls 61 and a third device 71. The encapsulant 51 covers the routing circuitry 21, the second device 27 and the bonding wires 41 from below, and surrounds and conformally coats and covers sidewalls of the second device 27 in the lateral directions. The solder balls 61 are electrically coupled to the circuit board 30 from the second side 302 of the circuit board 30. The third device 71 is electrically coupled to the circuit board 30 through solder balls 63 from the first side 301 of the circuit board 30.

FIG. 15 is a cross-sectional view of the semiconductor assembly 120 of FIG. 13 further provided with a third device 71 and passive components 73 electrically coupled to the circuit board 30 from the first side 301 of the circuit board 30. The third device 71, illustrated as a semiconductor chip, is attached on the heat spreader 81 and electrically coupled to the conductive traces 333 of the circuit board 30 through bonding wires 43. The passive components 73 are mounted on and electrically coupled to the conductive traces 333 of the circuit board 30.

FIG. 16 is a cross-sectional view of the semiconductor assembly 120 of FIG. 15 further provided with encapsulants 51, 53 and solder balls 61. The encapsulant 51 covers the routing circuitry 21, the second device 27 and the bonding wires 41 from below, and surrounds and conformally coats and covers sidewalls of the second device 27 in the lateral directions. The encapsulant 53 covers the bonding wires 43, the circuit board 30, the third device 71, the heat spreader 81 and the passive components 73 from above, and surrounds and conformally coats and covers sidewalls of the third device 71 in the lateral directions. The solder balls 61 are electrically coupled to the circuit board 30 from the second side 302 of the circuit board 30.

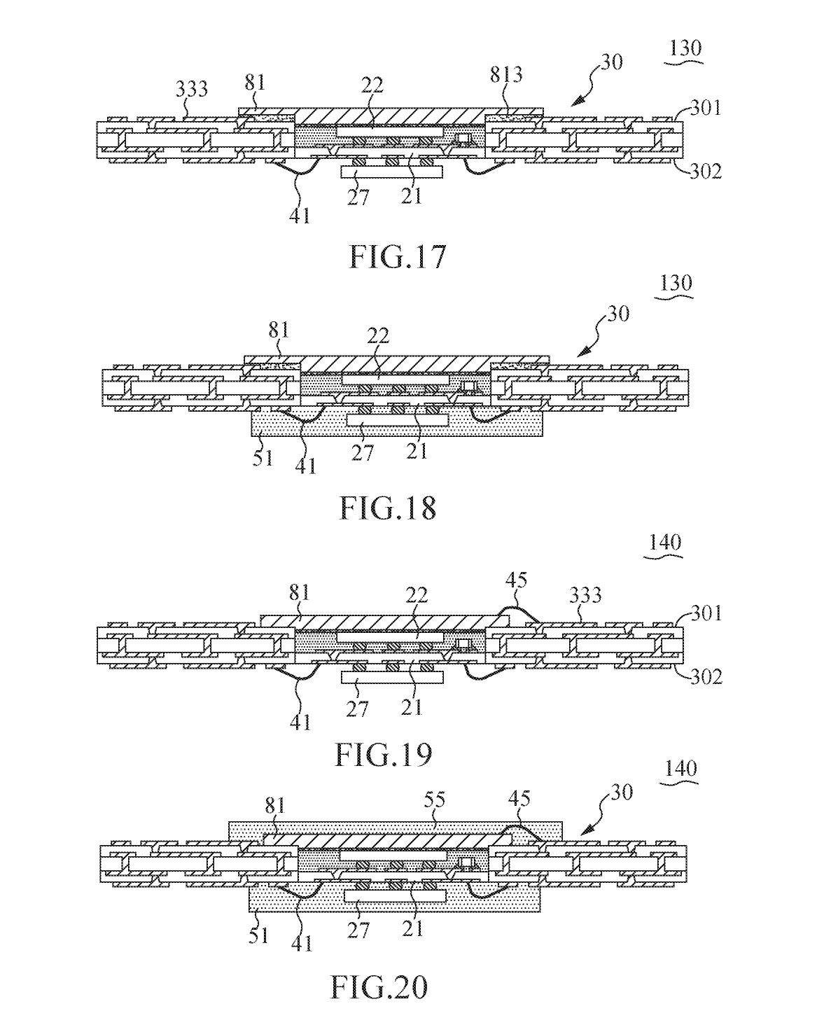

FIG. 17 is a cross-sectional view of yet another aspect of the semiconductor assembly according to the first embodiment of the present invention. The semiconductor assembly 130 is similar to that illustrated in FIG. 13, except that the heat spreader 81 is further attached on the conductive traces 333 through an electrically conductive material 813. In this aspect, the electrically conductive material 813 is illustrated as an electrically conductive adhesive. However, in some cases, a solder may be used as the electrically conductive material 813. As a result, the heat spreader 81 made of an electrically and thermally conductive material can be electrically coupled to the circuit board 30 for ground connection.

FIG. 18 is a cross-sectional view of the semiconductor assembly 130 of FIG. 17 further provided with an encapsulant 51. The encapsulant 51 covers the bonding wires 41, the routing circuitry 21 and the second device 27 as well as selected portions of the circuit board 30 from below.

FIG. 19 is a cross-sectional view of yet another aspect of the semiconductor assembly according to the first embodiment of the present invention. The semiconductor assembly 140 is similar to that illustrated in FIG. 13, except that the heat spreader 81 is further electrically coupled to the conductive traces 333 at the first side 301 of the circuit board 30 through a bonding wire 45 for ground connection.

FIG. 20 is a cross-sectional view of the semiconductor assembly 140 of FIG. 19 further provided with encapsulants 51, 55. The encapsulant 51 covers the bonding wires 41, the routing circuitry 21 and the second device 27 as well as selected portions of the circuit board 30 from below, and surrounds and conformally coats and covers sidewalls of the second device 27 in the lateral directions. The encapsulant 55 covers the bonding wire 45 and the heat spreader 81 as well as selected portions of the circuit board 30 from above.

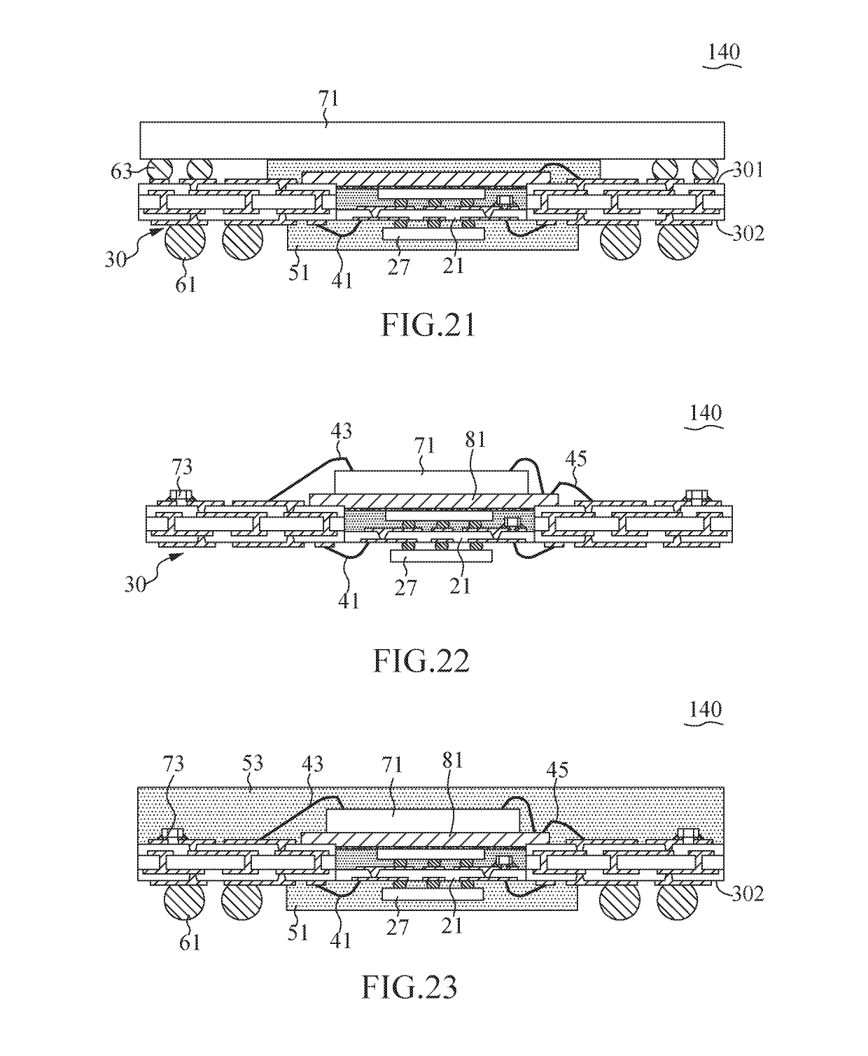

FIG. 21 is a cross-sectional view of the semiconductor assembly 140 of FIG. 20 further provided with solder balls 61 and a third device 71 mounted on the opposite sides of the circuit board 30, respectively. The solder balls 61 are electrically coupled to the circuit board 30 from the second side 302 of the circuit board 30. The third device 71 is electrically coupled to the circuit board 30 through solder balls 63 from the first side 301 of the circuit board 30.

FIG. 22 is a cross-sectional view of the semiconductor assembly 140 of FIG. 19 further provided with a third device 71 electrically coupled to the circuit board 30 and the heat spreader 81 and passive components 73 mounted on the circuit board 30. The third device 71 is attached on the heat spreader 81 and electrically coupled to the circuit board 30 for signal routing and to the heat spreader 81 for ground connection through bonding wires 43.

FIG. 23 is a cross-sectional view of the semiconductor assembly 140 of FIG. 22 further provided with encapsulants 51, 53 and solder balls 61. The encapsulant 51 covers the bonding wires 41, the routing circuitry 21 and the second device 27 from below, and surrounds and conformally coats and covers sidewalls of the second device 27 in the lateral directions. The encapsulant 53 covers the bonding wires 43, 45, the third device 71, the passive components 73, the heat spreader 81 and the circuit board 30 from above, and surrounds and conformally coat and cover sidewalls of the third device 71 in the lateral directions. The solder balls 61 are electrically coupled to the circuit board 30 from the second side 302 of the circuit board 30.

### Embodiment 2

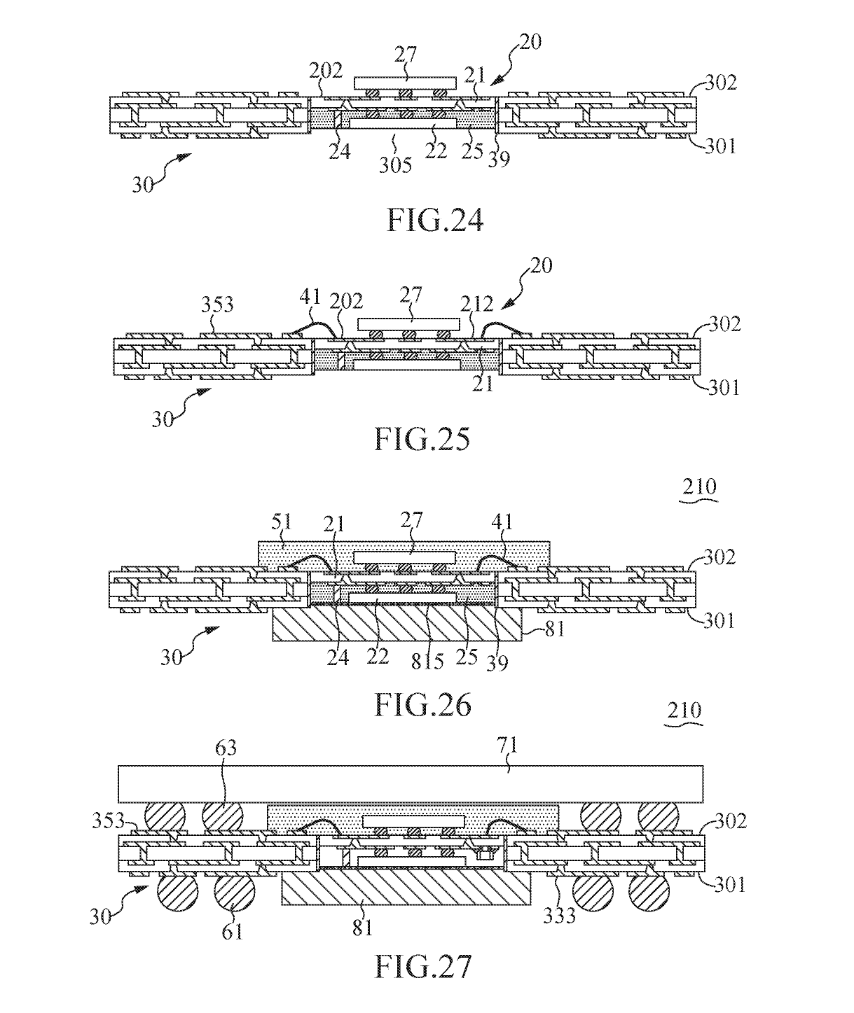

FIGS. 24-26 are schematic views showing a method of making a semiconductor assembly in which the face-to-face semiconductor sub-assembly 20 further includes a metal pillar electrically coupled to the heat spreader in accordance with the second embodiment of the present invention.

For purposes of brevity, any description in Embodiment 1 above is incorporated herein insofar as the same is applicable, and the same description need not be repeated.

FIG. 24 is a cross-sectional view of the structure with a face-to-face semiconductor sub-assembly 20 accommodated in a through opening 305 of a circuit board 30. The face-to-face semiconductor sub-assembly 20 and the circuit board 30 are similar to those illustrated in FIGS. 7 and 8, respectively, except that the face-to-face semiconductor sub-assembly 20 further includes a metal pillar 24 electrically coupled to the routing circuitry 21 and encapsulated in the molding compound material 25, and the circuit board 30 further includes a metal layer 39 disposed on sidewalls of the through opening 305. In this illustration, the second surface 202 of the routing circuitry 21 and the second side 302 of the circuit board 30 face in the upward direction, and the metal layer 39 of the circuit board 30 surrounds the peripheral edges of the routing circuitry 21 and the molding compound material 25.

FIG. 25 is a cross-sectional view of the structure with bonding wires 41 attached to the face-to-face semiconductor sub-assembly 20 and the circuit board 30. The bonding wires 41 contact and are electrically coupled to the routing traces 212 at the second surface 202 of the routing circuitry 21 and the conductive traces 353 at the second side 302 of the circuit board 30.

FIG. 26 is a cross-sectional view of the structure further provided with an encapsulant 51 and a heat spreader 81. The encapsulant 51 covers the routing circuitry 21, the second device 27 and the bonding wires 41 as well as selected portions of the circuit board 30 from above, and surrounds and conformally coats and covers sidewalls of the second device 27 in the lateral directions. The heat spreader 81 is attached to the first device 22, the metal pillar 24, the molding compound material 25 and the circuit board 30 using a thermally and electrically conductive adhesive 815.

Accordingly, as shown in FIG. 26, a semiconductor assembly 210 is accomplished and includes a face-to-face semiconductor sub-assembly 20 electrically connected to a circuit board 30 by bonding wires 41 and thermally conductible to a heat spreader 81. In this illustration, the face-to-face semiconductor sub-assembly 20 includes a routing circuitry 21, a first device 22, a metal pillar 24, a molding compound material 25 and a second device 27.

The first device 22 and the second device 27 are disposed at two opposite sides of the routing circuitry 21 and face-to-face electrically connected to each other through the routing circuitry 21 therebetween. As such, the routing circuitry 21 offers the shortest interconnection distance between the first device 22 and the second device 27, and provides first level fan-out routing for the first device 22 and the second device 27. The metal pillar 24 is electrically connected to the routing circuitry 21 and extends through the molding compound material 25. The heat spreader 81 is electrically connected to the metal pillar 24 and the metal layer 39 through a thermally and electrically conductive adhesive for ground connection and thermally conductible to the first device 22 for heat dissipation. As a result, the metal layer 39 and the heat spreader 81 can offers effective EMI (electromagnetic interference) shielding for the first device 22. The circuit board 30 is electrically coupled to the routing circuitry 21 using the bonding wires 41, and provides second level fan-out routing for the routing circuitry 21.

FIG. 27 is a cross-sectional view of the semiconductor assembly 210 of FIG. 26 further provided with solder balls 61 and a third device 71 mounted on the opposite sides of the circuit board 30, respectively. The solder balls 61 are mounted on conductive traces 333 at the first side 301 of the circuit board 30, and extend beyond the outer surface of the heat spreader 81 in the downward direction to ensure successful next-level connection. The third device 71 is electrically coupled to the circuit board 30 through solder balls 63 in contact with the third device 71 and the conductive traces 353 at the second side 302 of the circuit board 30.

### Embodiment 3

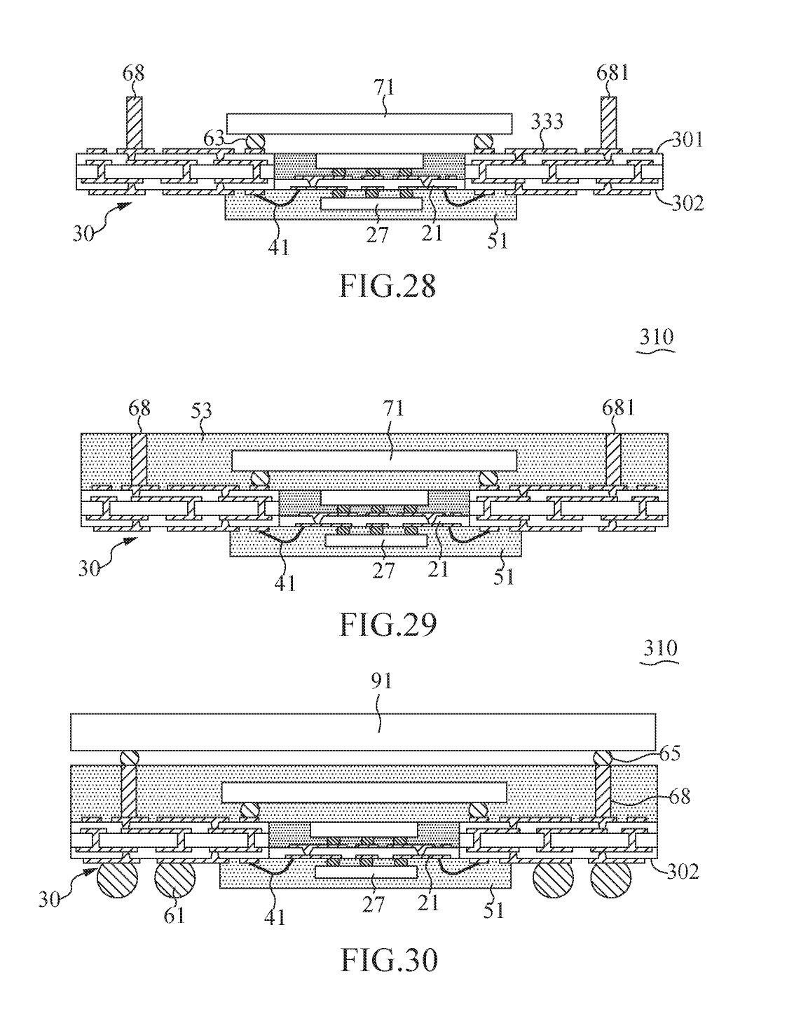

FIGS. 28-29 are schematic views showing a method of making a semiconductor assembly having vertical connecting elements on the circuit board and a third device flip-chip mounted on the circuit board in accordance with the third embodiment of the present invention.

For purposes of brevity, any description in Embodiments above is incorporated herein insofar as the same is applicable, and the same description need not be repeated.

FIG. 28 is a cross-sectional view of the structure of FIG. 11 further provided with vertical connecting elements 68 and a third device 71 electrically coupled to the circuit board 30 from the first side 301 of the circuit board 30. In this illustration, the vertical connecting elements 68 are illustrated as metal posts 681 and contact the conductive traces 333 of the circuit board 30. The third device 71 is electrically coupled to the conductive traces 333 of the circuit board 30 through solder balls 63.

FIG. 29 is a cross-sectional view of the structure of FIG. 28 further provided with an encapsulant 53 to finish the fabrication of a semiconductor assembly 310. The encapsulant 53 covers the circuit board 30 and the third device 71 from above, and surrounds and conformally coats and covers sidewalls of the third device 71 and the vertical connecting elements 68 in the lateral directions.

FIG. 30 is a cross-sectional view of the semiconductor assembly 310 of FIG. 29 further provided with solder balls 61 and a fourth device 91. The solder balls 61 are electrically coupled to the circuit board 30 from the second side 302 of the circuit board 30. The fourth device 91 is electrically coupled to the vertical connecting elements 68 through solder balls 65.

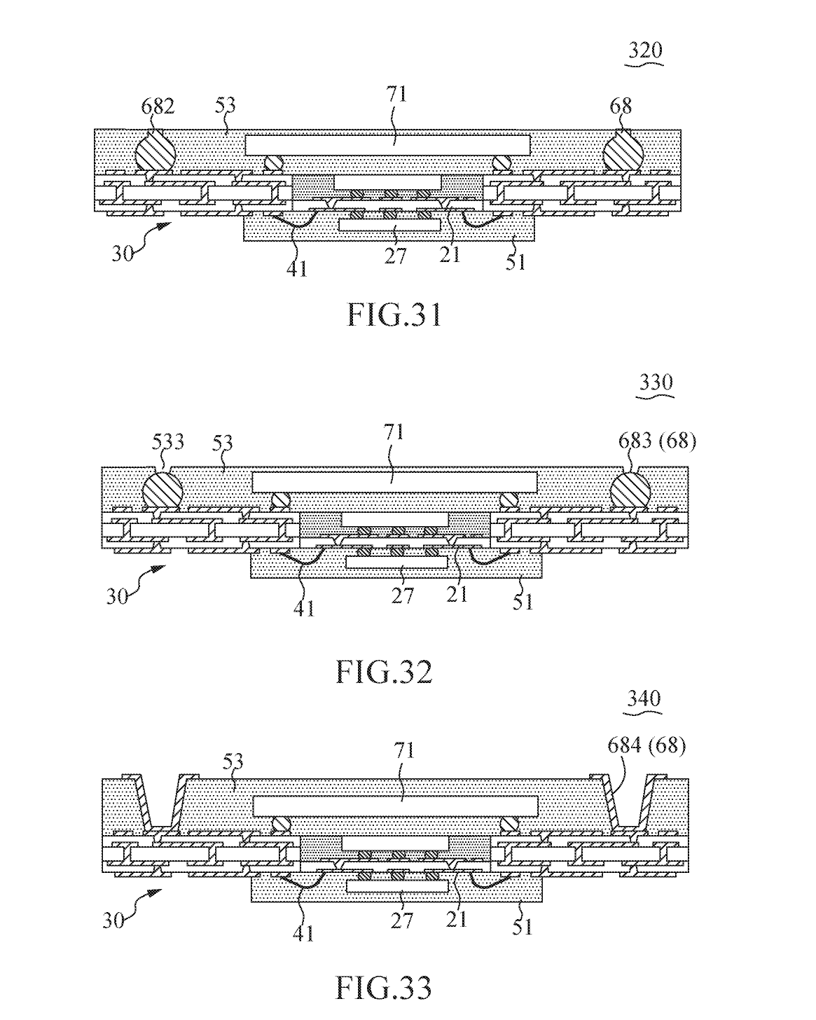

FIG. 31 is a cross-sectional view of another aspect of the semiconductor assembly according to the third embodiment of the present invention. The semiconductor assembly 320 is similar to that illustrated in FIG. 29, except that it includes stud bumps 682 as the vertical connecting elements 68.

FIG. 32 is a cross-sectional view of yet another aspect of the semiconductor assembly according to the third embodiment of the present invention. The semiconductor assembly 330 is similar to that illustrated in FIG. 29, except that it includes solder balls 683 as the vertical connecting elements 68 and the encapsulant 53 has openings 533 to expose the solder balls 683 from above.

FIG. 33 is a cross-sectional view of yet another aspect of the semiconductor assembly according to the third embodiment of the present invention. The semiconductor assembly 340 is similar to that illustrated in FIG. 29, except that it includes conductive vias 684 as the vertical connecting elements 68.

### Embodiment 4

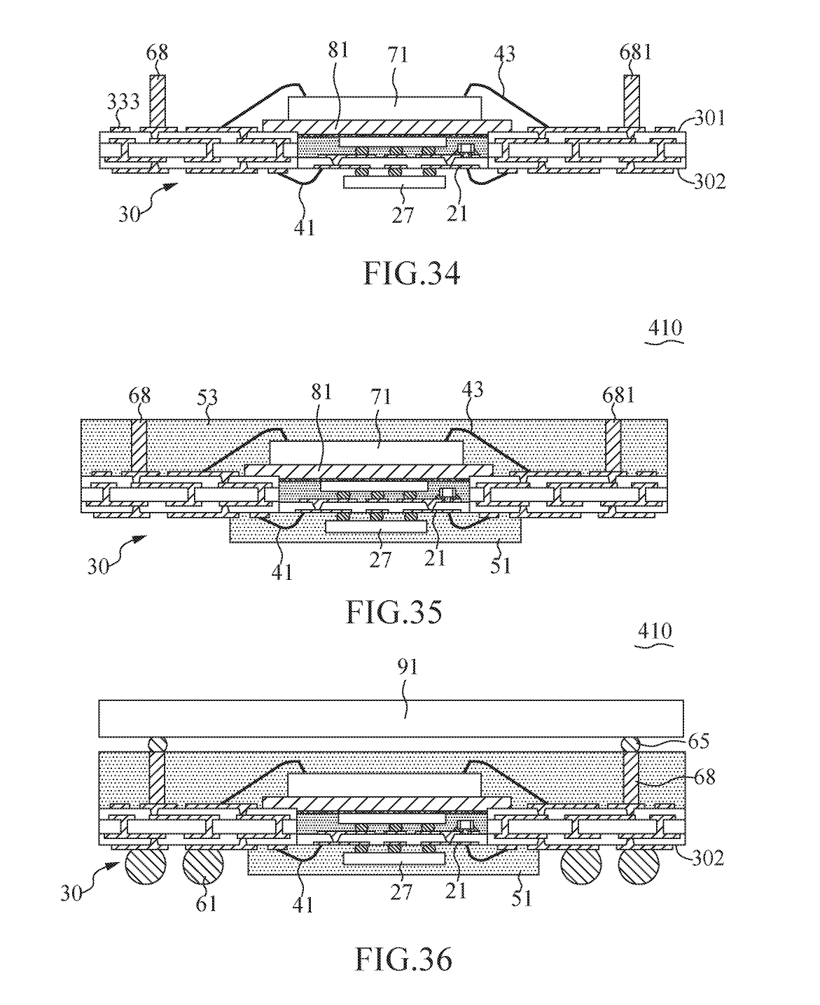

FIGS. 34-35 are schematic views showing a method of making a semiconductor assembly having vertical connecting elements on the circuit board and a third device wire bonded to the circuit board in accordance with the fourth embodiment of the present invention.

For purposes of brevity, any description in Embodiments above is incorporated herein insofar as the same is applicable, and the same description need not be repeated.

FIG. 34 is a cross-sectional view of the structure of FIG. 13 further provided with vertical connecting elements 68 and a third device 71 electrically coupled to the circuit board 30 from the first side 301 of the circuit board 30. In this illustration, the vertical connecting elements 68 are illustrated as metal posts 681 and contact the conductive traces 333 of the circuit board 30. The third device 71 is attached on the heat spreader 81 and electrically coupled to the conductive traces 333 of the circuit board 30 through bonding wires 43.

FIG. 35 is a cross-sectional view of the structure of FIG. 34 further provided with encapsulants 51, 53 to finish the fabrication of a semiconductor assembly 410. The encapsulant 51 covers the routing circuitry 21, the second device 27 and the bonding wires 41 from below, and surrounds and conformally coats and covers sidewalls of the second device 27 in the lateral directions. The encapsulant 53 covers the bonding wires 43, the circuit board 30, the third device 71 and the heat spreader 81 from above, and surrounds and conformally coats and covers sidewalls of the third device 71 and the vertical connecting elements 68 in the lateral directions.

FIG. 36 is a cross-sectional view of the semiconductor assembly 410 of FIG. 35 further provided with solder balls 61 and a fourth device 91. The solder balls 61 are electrically coupled to the circuit board 30 from the second side 302 of the circuit board 30. The fourth device 91 is electrically coupled to the vertical connecting elements 68 through solder balls 65.

The semiconductor assemblies described above are merely exemplary. Numerous other embodiments are contemplated. In addition, the embodiments described above can be mixed-and-matched with one another and with other embodiments depending on design and reliability considerations. For instance, the circuit board may have multiple through openings in an array and each face-to-face semiconductor sub-assembly is accommodated in its corresponding through opening. Also, the circuit board can include additional conductive traces to receive and route additional face-to-face semiconductor sub-assemblies.

As illustrated in the aforementioned embodiments, a distinctive semiconductor assembly is configured and includes a face-to-face semiconductor sub-assembly electrically coupled to a circuit board by bonding wires. Optionally, an encapsulant may be further provided to cover the bonding wires. For the convenience of below description, the direction in which the first surface of the routing circuitry and the first side of the circuit board face is defined as the first direction, and the direction in which the second surface of the routing circuitry and the second side of the circuit board face is defined as the second direction.

The face-to-face semiconductor sub-assembly includes a first device and a second device electrically connected to each other. More specifically, the face-to-face semiconductor sub-assembly can further include a routing circuitry between the first device and the second device, and optionally includes a molding compound material surrounding the first device and covering the first surface of the routing circuitry. In a preferred embodiment, the face-to-face semiconductor sub-assembly is prepared by the steps of: electrically coupling the first device to the first surface of the routing circuitry detachably adhered over a sacrificial carrier; optionally providing the molding compound material over the routing circuitry and around the first device; removing the sacrificial carrier from the routing circuitry; and electrically coupling the second device to the second surface of the routing circuitry. As a result, the first and second devices, respectively disposed over the first and second surfaces of the routing circuitry, can be electrically connected to each other by the routing circuitry.

The first and second devices can be semiconductor chips, packaged devices, or passive components. The first device can be electrically coupled to the routing circuitry by a well-known flip chip bonding process with its active surface facing in the routing circuitry using bumps without metallized vias in contact with the first device. Likewise, after removal of the sacrificial carrier, the second device can be electrically coupled to the routing circuitry by a well-known flip chip bonding process with its active surface facing in the routing circuitry using bumps without metallized vias in contact with the second device.

The routing circuitry can be a buildup circuitry without a core layer to provide primary fan-out routing/interconnection and the shortest interconnection distance between the first and second devices. Preferably, the routing circuitry is a multi-layered buildup circuitry and can include at least one dielectric layer and conductive traces that fill up via openings in the dielectric layer and extend laterally on the dielectric layer. The dielectric layer and the conductive traces are serially formed in an alternate fashion and can be in repetition when needed. Accordingly, the routing circuitry can be formed with electrical contacts at its first and second surfaces for first device connection from the first surface and second device connection and next-level connection from the second surface.

The circuit board has a through opening that extends through the circuit board between first and second sides thereof to accommodate the face-to-face semiconductor sub-assembly therein. In a preferred embodiment, the first device, the routing circuitry and the optional molding compound material are located within the through opening of the circuit board, whereas the second device is located beyond the through opening of the circuit board. The peripheral edges of the face-to-face semiconductor sub-assembly can be attached to sidewalls of the through opening of the circuit board by dispensing an adhesive therebetween. Alternatively, the encapsulant, provided to cover the bonding wires, may further fill up gaps between the peripheral edges of the face-to-face semiconductor sub-assembly and the sidewalls of the through opening of the circuit board. Accordingly, the interior sidewalls of the circuit board can laterally surround and be mechanically bonded to the peripheral edges of the dielectric layer of the routing circuitry and the molding compound material by the adhesive or the encapsulant. The circuit board is not limited to a particular structure, and for instance, may include a core layer, first and second buildup circuitries and metallized through vias. The first and second buildup circuitries are disposed on both opposite sides of the core layer. The metallized through vias extend through the core layer and provide electrical connections between the first and second buildup circuitries. Each of the first and second buildup circuitries typically includes an insulating layer and one or more conductive traces. The insulating layers of the first and second buildup circuitries are respectively deposited on opposite sides of the core layer. The conductive traces extend laterally on the insulating layer and include conductive vias in contact with first and second patterned wiring layers of the core layer. Further, the first and second buildup circuitries can include additional insulating layers, additional via openings, and additional conductive traces if needed for further signal routing. The outmost conductive traces of the first and second buildup circuitries can respectively accommodate conductive joints, such as solder balls or bonding wires, for electrical communication and mechanical attachment with an assembly or electronic device. For instance, a third device can be further provided to be located beyond the through opening of the circuit board, and electrically coupled to the circuit board from the first side or the second side of the circuit board. More specifically, the third device may be a semiconductor chip and electrically coupled to the circuit board through a plurality of bonding wires, or be a ball grid array package or a bumped chip and electrically coupled to the circuit board through a plurality of solder balls. Additionally, the circuit board may include a metal layer disposed on the sidewalls of the through opening. As such, the metal layer can offer EMI shielding for the first device.

The bonding wires provide electrical connections between the routing circuitry of the sub-assembly and the circuit board. In a preferred embodiment, the bonding wires contact and are attached to the second surface of the routing circuitry and the second side of the circuit board. As a result, the first and second devices can be electrically connected to the circuit board for external connection through the routing circuitry and the bonding wires.

The semiconductor assembly of the present invention may further include a heat spreader thermally conductible to the first device. In a preferred embodiment, the heat spreader is disposed over the first side of the circuit board, and may further extend into the through opening of the circuit board. For ground connection, the heat spreader can be electrically coupled to the circuit board through a bonding wire, a solder or an electrically conductive adhesive.

Optionally, an array of vertical connecting elements may be further provided to be electrically coupled to the circuit board for next-level connection. Preferably, the vertical connecting elements contact and are electrically coupled to the circuit board from the first side of the circuit board and located around the third device. The vertical connecting elements can include metal posts, solder balls, conductive vias or stud bumps, and may be laterally covered by an encapsulant. As the vertical connecting elements have a selected portion not covered by the encapsulant, a fourth device can be further provided to be electrically coupled to the vertical connecting elements.

The term “cover” refers to incomplete or complete coverage in a vertical and/or lateral direction. For instance, in a preferred embodiment, the heat spreader covers the first device in the first direction regardless of whether another element such as the thermally conductive adhesive is between the first device and the heat spreader.

The phrases “attached to”, “attached on” and “mounted on” includes contact and non-contact with a single or multiple element(s). For instance, in a preferred embodiment, the peripheral edges of the face-to-face semiconductor sub-assembly are attached to the sidewalls of the through opening of the circuit board regardless of whether the peripheral edges of the sub-assembly are separated from the interior sidewalls of the circuit board by the adhesive or the encapsulant.

The phrases “electrical connection”, “electrically connected” and “electrically coupled” refer to direct and indirect electrical connection. For instance, in a preferred embodiment, the bonding wires directly contact and are electrically connected to the circuit board, and the routing circuitry is spaced from and electrically connected to the circuit board by the bonding wires.

The “first direction” and “second direction” do not depend on the orientation of the semiconductor assembly, as will be readily apparent to those skilled in the art. For instance, the first surface of the routing circuitry and the first side of the circuit board face the first direction and the second surface of the routing circuitry and the second side of the circuit board face the second direction regardless of whether the semiconductor assembly is inverted. Thus, the first and second directions are opposite one another and orthogonal to the lateral directions.

The semiconductor assembly according to the present invention has numerous advantages. For instance, the first and second devices are mounted on opposite sides of the routing circuitry, which can offer primary fan-out routing/interconnection and the shortest interconnect distance between the first and second devices. The circuit board offers a second level fan-out routing/interconnection and 3D vertical connection, and also provides mechanical support for the assembly. As the routing circuitry of the sub-assembly are connected to the circuit board by bonding wires, not by direct build-up process, the simplified process steps result in lower manufacturing cost. The heat spreader can provide thermal dissipation, electromagnetic shielding and moisture barrier for the first device. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A semiconductor assembly with three dimensional integration, comprising:
a face-to-face semiconductor sub-assembly that includes a first device, a second device and a routing circuitry, wherein the first device is electrically coupled to a first surface of the routing circuitry and the second device is electrically coupled to a second surface of the routing circuitry opposite to the first surface;
a circuit board having a through opening, wherein the face-to-face semiconductor sub-assembly is disposed in the through opening of the circuit board; and
a plurality of bonding wires that electrically couple the routing circuitry to the circuit board.

2. The semiconductor assembly of claim 1, further comprising a heat spreader that is disposed over the circuit board and thermally conductible to the first device.

3. The semiconductor assembly of claim 2, wherein the heat spreader has a selected portion further extending into the through opening of the circuit board.

4. The semiconductor assembly of claim 2, wherein the heat spreader is electrically coupled to the circuit board through a bonding wire, a solder or an electrically conductive adhesive.

5. The semiconductor assembly of claim 1, further comprising a molding compound that surrounds the first device and covers the first surface of the routing circuitry.

6. The semiconductor assembly of claim 1, further comprising an encapsulant that covers the bonding wires.

7. The semiconductor assembly of claim 1, further comprising a third device electrically coupled to the circuit board.

8. The semiconductor assembly of claim 7, wherein the third device is a semiconductor chip and electrically coupled to the circuit board through a plurality of additional bonding wires.

9. The semiconductor assembly of claim 7, wherein the third device is a ball grid array package or a bumped chip and electrically coupled to the circuit board through a plurality of solder balls.

10. The semiconductor assembly of claim 7, further comprising an array of vertical connecting elements electrically coupled to the circuit board and located around the third device.

11. The semiconductor assembly of claim 10, further comprising a fourth device electrically coupled to the vertical connecting elements.

12. The semiconductor assembly of claim 1, wherein the circuit board includes a metal layer disposed on sidewalls of the through opening.

13. A method of making a semiconductor assembly, comprising:
providing a face-to-face semiconductor sub-assembly that includes a first device and a second device face-to-face electrically connected to each other;
providing a circuit board that has a through opening;
disposing the face-to-face semiconductor sub-assembly in the through opening of the circuit board;
electrically coupling the face-to-face semiconductor sub-assembly to the circuit board through a plurality of bonding wires; and
electrically coupling a third device to the circuit board.

14. The method of claim 13, further comprising a step of providing a heat spreader that is disposed over the circuit board and thermally conductible to the first device through a thermally conductive adhesive.

15. The semiconductor assembly of claim 13, further comprising a step of providing an encapsulant that covers the bonding wires.

16. The semiconductor assembly of claim 13, further comprising a step of forming an array of vertical connecting elements electrically coupled to the circuit board and located around the third device.

17. The semiconductor assembly of claim 16, further comprising a step of electrically coupling a fourth device to the vertical connecting elements.
